(19) United States
(12) Patent Application Publication
(10) Pub. No.: US 2026/0255483 A1
(43) Pub. Date: Aug. 27, 2026

(54) REDUCING VIA STUB LENGTH DURING PRINTED CIRCUIT BOARD FABRICATION

(71) Applicant: NVIDIA Corporation, Santa Clara, CA (US)

(72) Inventors: Duy NGUYEN, Rohnert Park, CA (US); Carmen A. CAPILLO, JR., Hollister, CA (US); Anh-Vu Tra LE, San Jose, CA (US)

(21) Appl. No.: 19/059,961

(22) Filed: Feb. 21, 2025

(51) Int. Cl. H05K 1/11; H05K 3/00; H05K 3/40

(52) U.S. Cl. CPC H05K 1/115; H05K 3/0047; H05K 3/4038

(57) ABSTRACT

Various embodiments include techniques for fabricating a printed circuit board (PCB). The PCB includes vias that connect signal traces between multiple signal layers of the PCB. The via is formed by drilling a hole through the PCB and applying a thin metal layer to the via to connect signal traces on multiple signal layers. If at least one of the other signal layers does not include a signal trace that connects to the via, the via is backdrilled from this outer signal layer towards an inner signal layer that does include a signal trace that connects to the via. Subsequently, a thicker metal layer is applied to the via to improve conduction, increase durability, and repair any damage that may have resulted from backdrilling. By performing this latter plating process after backdrilling, the via has little or no remaining stub, resulting in less electromagnetic interference relative to prior conventional approaches.

### BACKGROUND

### Field of the Various Embodiments

Various embodiments relate generally to printed circuit board manufacturing and, more specifically, to reducing via stub length during printed circuit board fabrication.

### Description of the Related Art

Printed circuit boards (PCBs) are used in various electronics devices, including laptop computers, smart phones, tablet computers, audio equipment, flat screen televisions, and so on. Electronic components are mounted to one or more outer surfaces of a PCB, and conductive pathways, typically made of copper, connect the pins of the various electronic components to one another. Such pathways are referred to as signal traces. Signal traces can be disposed on one or both outer conductive surfaces of the PCB, referred to as outer signal layers. In more complex PCBs, signal traces can also be disposed on one or more internal conductive layers, referred to as inner signal layers. The outer signal layers and inner signal layers are separated from one another by nonconductive layers composed of resins, fiberglass, phenolic materials, and/or other nonconductive materials.

In many cases, there is a need to connect a signal trace on one signal layer with a signal trace on another signal layer. Such a connection can be achieved by using a plated through hole, referred to as a via. For example, a via can be used to connect a signal trace on a first outer signal layer with a signal trace on one of the internal signal layers. The signal trace on a first outer signal layer and the signal trace on the internal signal layer are both routed to a common location on the PCB. A hole is drilled through the board from the first outer signal layer to the second outer signal layer. The via is formed by performing two plating processes on the hole. The first plating process includes one or both of electroless plating and flash plating. Electroless plating involves a chemical process to coat the inner walls of the vias, including the conductive signal traces and the nonconductive layer with metals and/or metal alloys. Flash plating involves depositing a very thin layer of metal to the electroless plated walls of the via by immersing the PCB in an electroplating bath and applying an electrical current bath. The second plating process includes panel plating, which increases the metal and/or metal alloy thickness of the via wall for improved conduction and durability.

The resulting via includes a first portion that connects the signal trace on the first outer signal layer to the signal trace on the internal signal layer. The resulting via further includes a second portion that connects the signal trace on the internal signal layer and ends at the second outer signal layer. This second portion of the via results from the plating processes but does not provide any signal connectivity. However, this second portion of the via can generate or be susceptible to electromagnetic interference. In particular, the second portion of the via can radiate energy from the signal traces connected to the via, which can cause interference to other signal traces. Further, this second portion of the via can cause electromagnetic interference by transferring energy from other signal traces to the signal traces connected to the via, which can cause interference to the signal connected to the via. This electromagnetic interference can reduce the performance of circuits on the PCB and/or can cause such circuits to malfunction.

To mitigate this electromagnetic interference, a backdrilling operation can be performed to remove the second portion. The backdrilling operation includes drilling from the second outer signal layer towards the internal signal layer. One problem with this backdrilling technique is that, in order to avoid damaging the first portion of the via, the backdrilling stops before at some distance from the internal signal layer, which leaves a stub. This stub extends from the internal signal layer towards the second outer signal layer. Even though the length of the stub is shorter than the length of the second portion of the via prior to the backdrilling, the stub can still radiate energy from the signal trace and/or transfer energy from other signal traces to the signal trace. As a result, the backdrilled via can still generate or be susceptible to electromagnetic interference.

As the foregoing illustrates, what is needed in the art are more effective techniques for reducing electromagnetic interference in printed circuit boards.

### SUMMARY

Various embodiments of the present disclosure set forth a method for fabricating a printed circuit board (PCB). The method includes performing a first plating process on a via disposed between a first outer signal layer of the PCB and a second outer signal layer of the PCB. The method further includes performing a first backdrilling process on the via from the first outer signal layer of the PCB to a first inner signal layer of the PCB. The method further includes, subsequent to performing the first backdrilling process on the via, performing a second plating process on the via.

Various embodiments of the present disclosure set forth a printed circuit board (PCB), comprising a first outer signal layer, a second outer signal layer, a first inner signal layer, and a via disposed between the first outer signal layer and the second outer signal layer. The via comprises a first stub that is disposed between the first outer signal layer and the first inner signal layer. The first stub has a nominal length of 1 mil.

Various embodiments of the present disclosure set forth a printed circuit board (PCB), comprising: a first outer signal layer, a second outer signal layer, a first inner signal layer, and a via disposed between the first outer signal layer and the second outer signal layer. The via is formed by performing a first plating process on a via disposed between a first outer signal layer of the PCB and a second outer signal layer of the PCB. The via is further formed by performing a first backdrilling process on the via from the first outer signal layer of the PCB to a first inner signal layer of the PCB. The via is further formed by, subsequent to performing the first backdrilling process on the via, performing a second plating process on the via. The via comprises a first stub that is disposed between the first outer signal layer and the first inner signal layer. The first stub has a nominal length of 1 mil.

Other embodiments include, without limitation, a system that implements one or more aspects of the disclosed techniques, and one or more computer readable media including instructions for performing one or more aspects of the disclosed techniques, as well as a method for performing one or more aspects of the disclosed techniques.

At least one technical advantage of the disclosed techniques relative to the prior art is that, with the disclosed techniques, the stub length of a via can be significantly reduced relative to conventional approaches. As a result, the vias generated by the disclosed backdrilling techniques can generate less electromagnetic interference and can be less susceptible to electromagnetic interference relative to backdrilling after panel plating is completed. These advantages represent one or more technological improvements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIGS. 1A-1E illustrate how vias on a PCB are fabricated by backdrilling the vias after panel plating, according to various embodiments;

FIG. 2 is a sequence diagram illustrating how a PCB is fabricated by backdrilling the vias after panel plating, according to various embodiments;

FIGS. 3A-3D illustrate how vias on a PCB are fabricated by backdrilling the vias before panel plating, according to various embodiments;

FIG. 4 is a sequence diagram illustrating how a PCB is fabricated by backdrilling the vias before panel plating, according to various embodiments;

FIG. 5 is a flow diagram of method steps for fabricating a printed circuit board, according to various embodiments; and

FIG. 6 is a block diagram of a computing system configured to implement one or more aspects of the various embodiments.

### DETAILED DESCRIPTION

In the following description, numerous specific details are set forth to provide a more thorough understanding of the various embodiments. However, it will be apparent to one skilled in the art that the inventive concepts may be practiced without one or more of these specific details.

### Reducing Via Stub Length from Backdrilling During PCB Fabrication

Various embodiments include techniques for fabricating a printed circuit board (PCB) that includes vias. A PCB is fabricated to include one or more outer signal layers and one or more inner signal layers that are separated from one another by a nonconductive material. One or more vias are formed by drilling a hole at a location where two or more signal traces on different signal layers meet. The vias are drilled through the PCB from one outer signal layer to the other outer signal layer. One or more first plating processes, such as electroless plating and flash plating, apply a thin layer of metal or metal alloy to the inside walls of the vias. If a via does not connect to signal traces on both outer signal layers of the PCB, then the via is backdrilled from an outer signal layer that does not connect to a signal trace toward an inner signal layer that does connect to a signal trace. The backdrilling process can leave a stub disposed between an inner signal layer and an outer signal layer. The stub can have a nominal length of 1 mil and a tolerance of +2 mils/−1 mil. As a result, the remaining stub length can range from a minimum of 0 mil (no stub) to a maximum of 3 mil.

Backdrilling close to the inner signal layer may result in minor damage to the inner signal layer connection from the via to the signal trace. This minor damage, if present, can be repaired by a subsequent second plating process, such as panel plating. Panel plating is performed after backdrilling to apply a thick metal or metal alloy layer to the via, thereby improving conduction and durability. An epoxy resin is applied to fill and insulate the resulting via, and subsequent other processes are performed to complete fabrication of the PCB.

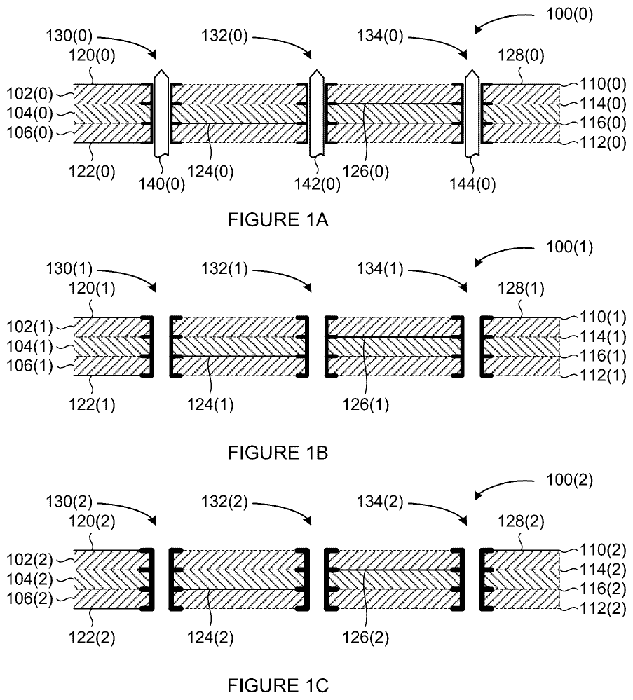

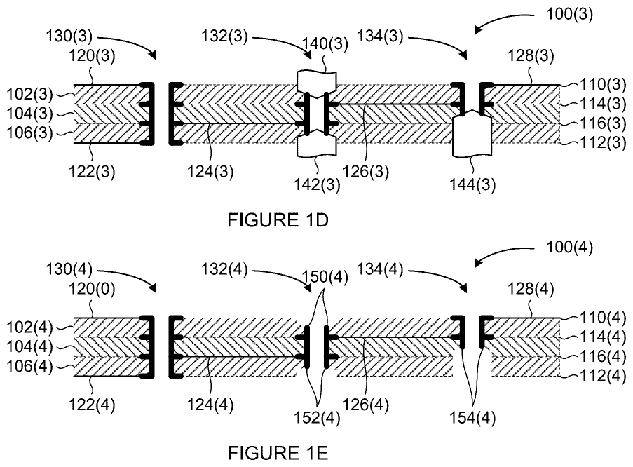

FIGS. 1A-1E illustrate how vias on a PCB are fabricated by backdrilling the vias after panel plating, according to various embodiments. As shown in FIG. 1A, the PCB 100(0) includes two outer signal layers 110(0), 112(0) and two inner signal layers 114(0), 116(0) separated by three nonconductive layers 102(0), 104(0), 106(0). The PCB 100(0) further includes a through hole 130(0), a buried via 132(0), and a blind via 134(0). As described herein, through hole 130(0), buried via 132(0), and blind via 134(0) are initially drilled and plated as through holes and then backdrilled, as needed, to fabricate buried vias and/or blind vias. A through hole, such as through hole 130(0), connects signal traces on both outer signal layers and optionally on one or more internal signal layers. For example, through hole 130(0) connects signal trace 120(0) on outer signal layer 110(0), signal trace 122(0) on outer signal layer 112(0), and signal trace 124(0) on internal signal layer 116(0). A buried via, such as buried via 132(0), connects signal traces on two or more internal signal layers. For example, buried via 132(0) connects signal trace 124(0) on internal signal layer 116(0) and signal trace 126(0) on internal signal layer 114(0). A blind via, such as blind via 134(0), connects signal traces on one of the outer signal layers and signal traces on one or more internal signal layers. For example, blind via 134(0) connects signal trace 128(0) on outer signal layer 110(0) and signal trace 126(0) on internal signal layer 114(0). Drill 140(0) forms through hole 130(0) by drilling through PCB 100(0) from outer signal layer 112(0) to outer signal layer 110(0). Drill 142(0) forms buried via 132(0) by drilling through PCB 100(0) from outer signal layer 112(0) to outer signal layer 110(0). Drill 144(0) forms blind via 134(0) by drilling through PCB 100(0) from outer signal layer 112(0) to outer signal layer 110(0). Drill 140(0), 142(0), and 144(0) can be a single drill that drills through hole 130(0), buried via 132(0), and blind via 134(0) serially. Additionally, or alternatively, drill 140(0), 142(0), and 144(0) can be multiple drills that drill two or more of through hole 130(0), buried via 132(0), or blind via 134(0) concurrently.

As shown in FIG. 1B, one or more first plating processes are applied to through hole 130(1), buried via 132(1), and blind via 134(1) to apply a thin layer of metal or metal alloy to the inside walls of the vias of PCB 100(1). The one or more first plating processes can include electroless plating, flash plating, and/or the like. Electroless plating involves a chemical process to coat the inner walls of the vias, including the conductive signal traces and the nonconductive layer with metals and/or metal alloys. Flash plating involves depositing a very thin layer of metal to the electroless plated walls of the via by immersing the PCB in an electroplating bath and applying an electrical current bath. The first plating processes apply the thin metal or metal alloy to through hole 130(1), buried via 132(1), and blind via 134(1) from outer signal layer 110(1) through inner signal layers 114(1), 116(1) and nonconductive layers 102(1), 104(1), 106(1) to outer signal layer 112(1). The first plating processes provide an electrical path between through hole 130(1), buried via 132(1), and blind via 134(1) and respective signal traces 120(1), 122(1), 124(1), 126(1), and 128(1).

As shown in FIG. 1C, one or more second plating processes are applied to through hole 130(2), buried via 132(2), and blind via 134(2) to apply a thicker layer of metal or metal alloy to the inside walls of the vias of PCB 100(2). The one or more second plating processes can include panel plating, and/or other plating processes. Panel plating increases the metal and/or metal alloy thickness of the via wall for improved conduction and durability. The second plating processes apply the thick metal or metal alloy to through hole 130(2), buried via 132(2), and blind via 134(2) from outer signal layer 110(2) through inner signal layers 114(2), 116(2) and nonconductive layers 102(2), 104(2), 106(2) to outer signal layer 112(2). The second plating processes provide an electrical path with improved conduction and durability between through hole 130(2), buried via 132(2), and blind via 134(2) and respective signal traces 120(2), 122(2), 124(2), 126(2), and 128(2).

As shown in FIG. 1D, backdrilling is performed on both ends of buried via 132(3) of PCB 100(3) to remove metal or metal alloy on the portions of buried via 132(3) that are not used for connecting signal traces, such as signal traces 124(3) and 126(3). Drill 140(3) removes metal or metal alloy on the portion of buried via 132(3) between outer signal layer 110(3) and inner signal layer 114(3). Drill 142(3) removes metal or metal alloy on the portion of buried via 132(3) between outer signal layer 112(3) and inner signal layer 116(3). Backdrilling is performed on one end of blind via 134(3) of PCB 100(3) to remove metal or metal alloy on the portions of blind via 134(3) that is not used for connecting signal traces, such as signal traces 126(3) and 128(3). Drill 144(3) removes metal or metal alloy on the portion of blind via 134(3) between outer signal layer 110(3) and inner signal layer 114(3). Backdrilling is not performed on through hole 130(3) of PCB 100(3). Drill 140(3), 142(3), and 144(3) can be a single drill that drills through both ends of buried via 132(3) and one end of blind via 134(3) serially. Additionally, or alternatively, drill 140(3), 142(3), and 144(3) can be multiple drills that drill two or more of both ends of buried via 132(3) and one end of blind via 134(3) concurrently. During backdrilling, drills 140(3), 142(3), and 144(3) drill to a depth sufficient to remove metal or metal alloy from the walls of buried via 132(3) and blind via 134(3) without risking any damage to the portion of buried via 132(3) and blind via 134(3) that connect to signal trace 124(3) on inner signal layer 116(3) and signal trace 126(3) on inner signal layer 114(3). As a result, an electrical path remains after backdrilling between through hole 130(3), buried via 132(3), and blind via 134(3) and respective signal traces 120(3), 122(3), 124(3), 126(3), and 128(3).

As shown in FIG. 1E, the PCB 100(4) after backdrilling includes through hole 130(4), buried via 132(4), and blind via 134(4) that connect respective signal traces 120(4), 122(4), 124(4), 126(4), and 128(4). The holes for through hole 130(4), buried via 132(4), and blind via 134(4) all extend from outer signal layer 110(4) through inner signal layers 114(4), 116(4) and nonconductive layers 102(4), 104(4), 106(4) to outer signal layer 112(4). After backdrilling, buried via 132(4) has a first stub 150(4) extending from inner signal layer 114(4) toward outer signal layer 110(4). Buried via 132(4) also has a second stub 152(4) extending from inner signal layer 116(4) toward outer signal layer 112(4). Blind via 134(4) has a stub 154(4) extending from inner signal layer 114(4) toward outer signal layer 112(4). The length of stubs 150(4), 152(4), and 154(4) after backdrilling are sufficient to avoid of risk of damage to the portion of buried via 132(4) and blind via 134(4) that connect to signal trace 124(4) on inner signal layer 116(4) and signal trace 126(4) on inner signal layer 114(4). In some embodiments, the length of stubs 150(4), 152(4), and 154(4) after backdrilling is 6 mils+/−4 mils, resulting in a minimum length of 2 mils and a maximum length of 10 mils.

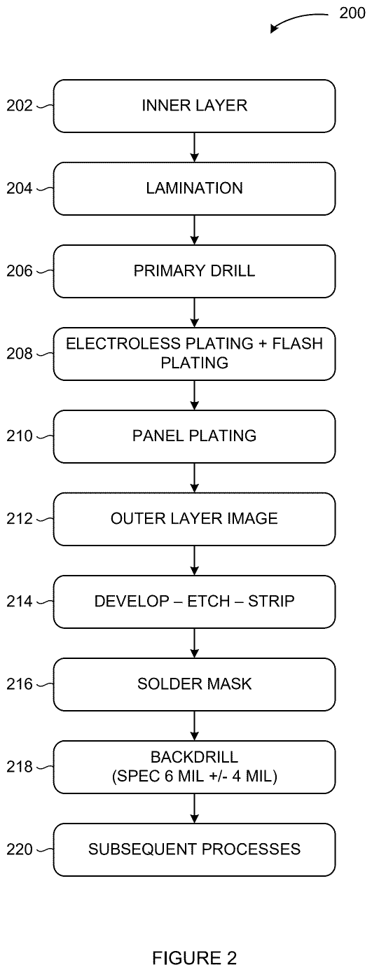

FIG. 2 is a sequence diagram 200 illustrating how a PCB is fabricated by backdrilling the vias after panel plating, according to various embodiments. As shown, an inner layer 202 process includes fabricating one or more nonconductive layers of the PCB. The nonconductive layers can be composed of resins, fiberglass, phenolic materials, and/or other nonconductive materials. Signal traces can be applied to one or both surfaces of the nonconductive layers. A metal or metal alloy is applied to one or both surfaces of a nonconductive layer, resulting in a nonconductive layer that has one or two conductive outer surfaces. A photosensitive material, referred to as photo resist, is applied to the conductive surface. The photoresist includes photoreactive chemicals that harden when exposed to ultraviolet light. A film with a negative image of signal traces is placed on top of the conductive surface to which the photoresist is applied. The conductive surface, with the film on top, is exposed to ultraviolet light, causing the portion of the metal or metal alloy under the clear portion of the film to harden. These areas exposed to ultraviolet are the signal traces for the conductive layer. The conductive layer is exposed to a first solution to remove the unhardened portion of the photoresist, a second solution to etch away the exposed portion of the conductive layer, and a third solution to strip away the hardened portion of the photo resist.

A lamination 204 process includes applying an adhesive to the various nonconductive layers to attach the nonconductive layers to one another, resulting in a multilayer board. After lamination 204 process, the PCB includes nonconductive layers and internal signal layers but does not include outer signal layers.

A primary drill 206 process includes drilling through holes, buried vias, and blind vias in the PCB. A through hole connects signal traces on both outer signal layers and optionally on one or more internal signal layers. A buried via connects signal traces on two or more internal signal layers. A blind via connects signal traces on one of the outer signal layers and signal traces on one or more internal signal layers. At primary drill 206 process, the through holes, buried vias, and blind vias are all drilled through the entire PCB, from one outer surface to the other outer surface.

At electroless plating +flash plating 208 process, one or more first plating processes are applied to the PCB. The one or more first plating processes can include electroless plating, flash plating, and/or other plating processes. Electroless plating involves a chemical process to coat the inner walls of the vias, including the conductive signal traces and the nonconductive layer with metals and/or metal alloys. Flash plating involves depositing a very thin layer of metal to the electroless plated walls of the via by immersing the PCB in an electroplating bath and applying an electrical current bath.

At panel plating 210 process, one or more second plating processes are applied to the PCB. The one or more second plating processes can include panel plating, and/or other plating processes. Panel plating increases the metal and/or metal alloy thickness of the via wall for improved conduction and durability.

At outer layer image 212 process, a metal or metal alloy is applied to one or both outer surfaces of the PCB, resulting in a multilayer PCB that has one or two conductive outer surfaces. A photosensitive material, referred to as photo resist, is applied to the conductive surface. The photoresist includes photoreactive chemicals that harden when exposed to ultraviolet light. A film with a negative image of signal traces is placed on top of the conductive surface to which the photoresist is applied.

At develop-etch-strip 214 process, the conductive surface, with the film on top, is exposed to ultraviolet light, causing the portion of the metal or metal alloy under the clear portion of the film to harden. These areas exposed to ultraviolet are the signal traces for the conductive layer. The conductive layer is exposed to a first solution to remove the unhardened portion of the photoresist, a second solution to etch away the exposed portion of the conductive layer, and a third solution to strip away the hardened portion of the photo resist. The resulting PCB now has signal traces on one or both outer layers.

At solder mask 216 process, a resin is applied to the outer surfaces of the PCB using an imaging process similar to the process to fabricate signal trace layers, described herein. The solder mask prevents solder from adhering to certain areas of the PCB when components are soldered to the fabricated PCB.

A backdrill 218 process includes drilling out metal from both sides of buried vias and from one side of blind vias to remove the portion of the vias that do not connect to signal traces. These portions of the vias result from the first plating processes and the second plating processes but do not provide any signal connectivity. However, these portions of the vias can generate or be susceptible to electromagnetic interference. The backdrill 218 process drills the unused portion of the vias to a depth sufficient to remove metal or metal alloy from the walls of buried vias and blind vias without risking any damage to the vias. In order to avoid risk of damage to the plated vias, the length of the remaining stubs after backdrilling is 6 mils+/−4 mils, resulting in a minimum length of 2 mils and a maximum length of 10 mils.

Subsequent processes 220 are then performed to complete fabrication of the PCB, including filling and insulating the resulting vias with an epoxy resin, as well as other subsequent processes.

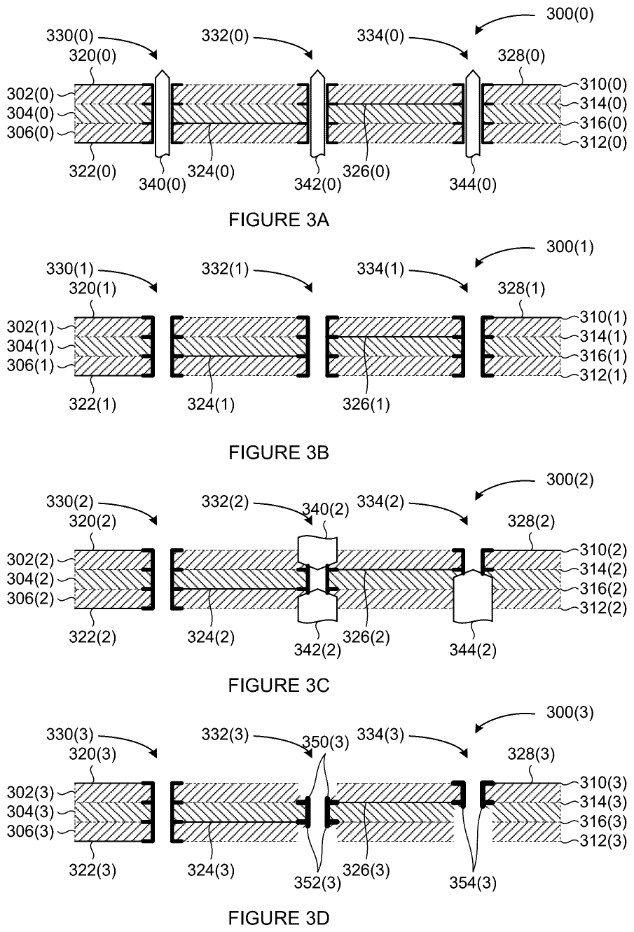

FIGS. 3A-3D illustrate how vias on a PCB are fabricated by backdrilling the vias before panel plating, according to various embodiments. As shown in FIG. 3A, the PCB 300(0) includes two outer signal layers 310(0), 312(0) and two inner signal layers 314(0), 316(0) separated by three nonconductive layers 302(0), 304(0), 306(0). The PCB 300(0) further includes a through hole 330(0), a buried via 332(0), and a blind via 334(0). As described herein, through hole 330(0), buried via 332(0), and blind via 334(0) are initially drilled and plated as through holes and then backdrilled, as needed, to fabricate buried vias and/or blind vias. A through hole, such as through hole 330(0), connects signal traces on both outer signal layers and optionally on one or more internal signal layers. For example, through hole 330(0) connects signal trace 320(0) on outer signal layer 310(0), signal trace 322(0) on outer signal layer 312(0), and signal trace 324(0) on internal signal layer 316(0). A buried via, such as buried via 332(0), connects signal traces on two or more internal signal layers. For example, buried via 332(0) connects signal trace 324(0) on internal signal layer 316(0) and signal trace 326(0) on internal signal layer 314(0). A blind via, such as blind via 334(0), connects signal traces on one of the outer signal layers and signal traces on one or more internal signal layers. For example, blind via 334(0) connects signal trace 328(0) on outer signal layer 310(0) and signal trace 326(0) on internal signal layer 314(0). Drill 340(0) forms through hole 330(0) by drilling through PCB 300(0) from outer signal layer 312(0) to outer signal layer 310(0). Drill 342(0) forms buried via 332(0) by drilling through PCB 300(0) from outer signal layer 312(0) to outer signal layer 310(0). Drill 344(0) forms blind via 334(0) by drilling through PCB 300(0) from outer signal layer 312(0) to outer signal layer 310(0). Drill 340(0), 342(0), and 344(0) can be a single drill that drills through hole 330(0), buried via 332(0), and blind via 334(0) serially. Additionally, or alternatively, drill 340(0), 342(0), and 344(0) can be multiple drills that drill two or more of through hole 330(0), buried via 332(0), or blind via 334(0) concurrently.

As shown in FIG. 3B, one or more first plating processes are applied to through hole 330(1), buried via 332(1), and blind via 334(1) to apply a thin layer of metal or metal alloy to the inside walls of the vias of PCB 300(1). The one or more first plating processes can include electroless plating, flash plating, and/or the like. Electroless plating involves a chemical process to coat the inner walls of the vias, including the conductive signal traces and the nonconductive layer with metals and/or metal alloys. Flash plating involves depositing a very thin layer of metal to the electroless plated walls of the via by immersing the PCB in an electroplating bath and applying an electrical current bath. The first plating processes apply the thin metal or metal alloy to through hole 330(1), buried via 332(1), and blind via 334(1) from outer signal layer 310(1) through inner signal layers 314(1), 316(1) and nonconductive layers 302(1), 304(1), 306(1) to outer signal layer 312(1). The first plating processes provide an electrical path between through hole 330(1), buried via 332(1), and blind via 334(1) and respective signal traces 320(1), 322(1), 324(1), 326(1), and 328(1).

As shown in FIG. 3C, backdrilling is performed on the vias of PCB 300(2) subsequent to the one or more first plating processes described in conjunction with FIG. 3B and prior to the one or more second plating processes described in conjunction with FIG. 3D. Backdrilling is performed on both ends of buried via 332(2) of PCB 300(2) to remove metal or metal alloy on the portions of buried via 332(2) that are not used for connecting signal traces, such as signal traces 324(2) and 326(2). Drill 340(2) removes metal or metal alloy on the portion of buried via 332(2) between outer signal layer 310(2) and inner signal layer 314(2). Drill 342(2) removes metal or metal alloy on the portion of buried via 332(2) between outer signal layer 312(2) and inner signal layer 316(2). Backdrilling is performed on one end of blind via 334(2) of PCB 300(2) to remove metal or metal alloy on the portions of blind via 334(2) that is not used for connecting signal traces, such as signal traces 326(2) and 328(2). Drill 344(2) removes metal or metal alloy on the portion of blind via 334(2) between outer signal layer 312(2) and inner signal layer 314(2). Backdrilling is not performed on through hole 330(2) of PCB 300(2). Drill 340(2), 342(2), and 344(2) can be a single drill that drills through both ends of buried via 332(2) and one end of blind via 334(2) serially. Additionally, or alternatively, drill 340(2), 342(2), and 344(2) can be multiple drills that drill two or more of both ends of buried via 332(2) and one end of blind via 334(2) concurrently. During backdrilling, drills 340(2), 342(2), and 344(2) drill to a depth sufficient to remove metal or metal alloy from the walls of buried via 332(2) and blind via 334(2). The depth of backdrilling can be close to or at the depth of buried via 332(2) and blind via 334(2) that connect to signal trace 324(2) on inner signal layer 316(2) and signal trace 326(2) on inner signal layer 314(2). Because the depth of backdrilling can be close to or at the depth of inner signal layer 314(2) and inner signal layer 316(2), the electrical path between through hole 330(2), buried via 332(2), and blind via 334(2) and respective signal traces 320(2), 322(2), 324(2), 326(2), and 328(2) can be subject to damage. Any damage resulting from backdrilling can be repaired by the one or more second plating processes described in conjunction with FIG. 3D.

As shown in FIG. 3D, one or more second plating processes are applied to through hole 330(3), buried via 332(3), and blind via 334(3) to apply a thicker layer of metal or metal alloy to the inside walls of the vias of PCB 300(3). The one or more second plating processes can include panel plating, and/or other plating processes. Panel plating increases the metal and/or metal alloy thickness of the via wall for improved conduction and durability. The second plating processes apply the thick metal or metal alloy to through hole 330(3), buried via 332(3), and blind via 334(3) from outer signal layer 310(3) through inner signal layers 314(3), 316(3) and nonconductive layers 302(3), 304(3), 306(3) to outer signal layer 312(3). The second plating processes provide an electrical path with improved conduction and durability between through hole 330(3), buried via 332(3), and blind via 334(3) and respective signal traces 320(3), 322(3), 324(3), 326(3), and 328(3).

The PCB 300(3) after backdrilling and second plating processes includes through hole 330(3), buried via 332(3), and blind via 334(3) that connect respective signal traces 320(3), 322(3), 324(3), 326(3), and 328(3). The holes for through hole 330(3), buried via 332(3), and blind via 334(3) all extend from outer signal layer 310(3) through inner signal layers 314(3), 316(3) and nonconductive layers 302(3), 304(3), 306(3) to outer signal layer 312(3). After backdrilling, buried via 332(3) has a first stub 350(3) extending from inner signal layer 314(3) toward outer signal layer 310(3). Buried via 332(3) also has a second stub 352(3) extending from inner signal layer 316(3) toward outer signal layer 312(3). Blind via 334(3) has a stub 354(3) extending from inner signal layer 314(3) toward outer signal layer 312(3). The length of stubs 350(3), 352(3), and 354(3) after backdrilling is minimal. Any damage caused by backdrilling to the portion of buried via 332(3) and blind via 334(3) that connect to signal trace 324(3) on inner signal layer 316(3) and signal trace 326(3) on inner signal layer 314(3) can be repaired by the second plating processes described in conjunction with FIG. 3D. In some embodiments, the length of stubs 350(3), 352(3), and 154(3) after backdrilling is 1 mil +2 mils /−1 mil, resulting in a minimum length of 0 mils and a maximum length of 3 mils.

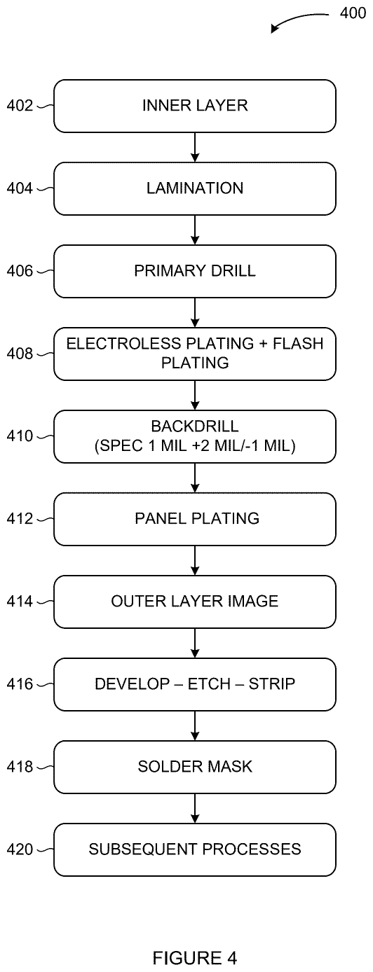

FIG. 4 is a sequence diagram 400 illustrating how a PCB is fabricated by backdrilling the vias before panel plating, according to various embodiments. As shown, an inner layer 402 process includes fabricating one or more nonconductive layers of the PCB. The nonconductive layers can be composed of resins, fiberglass, phenolic materials, and/or other nonconductive materials. Signal traces can be applied to one or both surfaces of the nonconductive layers. A metal or metal alloy is applied to one or both surfaces of a nonconductive layer, resulting in a nonconductive layer that has one or two conductive outer surfaces. A photosensitive material, referred to as photo resist, is applied to the conductive surface. The photoresist includes photoreactive chemicals that harden when exposed to ultraviolet light. A film with a negative image of signal traces is placed on top of the conductive surface to which the photoresist is applied. The conductive surface, with the film on top, is exposed to ultraviolet light, causing the portion of the metal or metal alloy under the clear portion of the film to harden. These areas exposed to ultraviolet are the signal traces for the conductive layer. The conductive layer is exposed to a first solution to remove the unhardened portion of the photoresist, a second solution to etch away the exposed portion of the conductive layer, and a third solution to strip away the hardened portion of the photo resist.

A lamination 404 process includes applying an adhesive to the various nonconductive layers to attach the nonconductive layers to one another, resulting in a multilayer board. After lamination 404 process, the PCB includes nonconductive layers and internal signal layers, but does not include outer signal layers.

A primary drill 406 process includes drilling through holes, buried vias, and blind vias in the PCB. A through hole connects signal traces on both outer signal layers and optionally on one or more internal signal layers. A buried via connects signal traces on two or more internal signal layers. A blind via connects signal traces on one of the outer signal layers and signal traces on one or more internal signal layers. At primary drill 406 process, the through holes, buried vias, and blind vias are all drilled through the entire PCB, from one outer surface to the other outer surface.

At electroless plating+flash plating 408 process, one or more first plating processes are applied to the PCB. The one or more first plating processes can include electroless plating, flash plating, and/or other plating processes. Electroless plating involves a chemical process to coat the inner walls of the vias, including the conductive signal traces and the nonconductive layer with metals and/or metal alloys. Flash plating involves depositing a very thin layer of metal to the electroless plated walls of the via by immersing the PCB in an electroplating bath and applying an electrical current bath.

A backdrill 410 process includes drilling out metal from both sides of buried vias and from one side of blind vias to remove the portion of the vias that do not connect to signal traces. These portions of the vias result from the first plating processes and the second plating processes, but do not provide any signal connectivity. However, these portions of the vias can generate or be susceptible to electromagnetic interference. The backdrill 410 process drills the unused portion of the vias to a depth sufficient to remove metal or metal alloy from the walls of buried vias and blind vias.

The depth of backdrilling can be close to or at the depth of the buried vias and blind vias that connect to signal traces on inner signal layers. Because the depth of backdrilling can be close to or at the depth of the inner signal layers, the electrical paths between the buried vias, blind vias, and respective signal traces can be subject to damage. The length of the remaining stubs after backdrilling is 1 mil+2 mils /−1 mil, resulting in a minimum length of 0 mils and a maximum length of 3 mils. Any damage resulting from backdrilling can be repaired by the one or more second plating processes described in panel plating 412 process.

At panel plating 412 process, one or more second plating processes are applied to the PCB. The one or more second plating processes can include panel plating, and/or other plating processes. Panel plating increases the metal and/or metal alloy thickness of the via wall for improved conduction and durability.

At outer layer image 414 process, a metal or metal alloy is applied to one or both outer surfaces of the PCB, resulting in a multilayer PCB that has one or two conductive outer surfaces. A photosensitive material, referred to as photo resist, is applied to the conductive surface. The photoresist includes photoreactive chemicals that harden when exposed to ultraviolet light. A film with a negative image of signal traces is placed on top of the conductive surface to which the photoresist is applied.

At develop-etch-strip 416 process, the conductive surface, with the film on top, is exposed to ultraviolet light, causing the portion of the metal or metal alloy under the clear portion of the film to harden. These areas exposed to ultraviolet are the signal traces for the conductive layer. The conductive layer is exposed to a first solution to remove the unhardened portion of the photoresist, a second solution to etch away the exposed portion of the conductive layer, and a third solution to strip away the hardened portion of the photo resist. The resulting PCB now has signal traces on one or both outer layers.

At solder mask 418 process, a resin is applied to the outer surfaces of the PCB using an imaging process similar to the process to fabricate signal trace layers, described herein. The solder mask prevents solder from adhering to certain areas of the PCB when components are soldered to the fabricated PCB.

Subsequent processes 420 are then performed to complete fabrication of the PCB, including filling and insulating the resulting vias with an epoxy resin, as well as other subsequent processes.

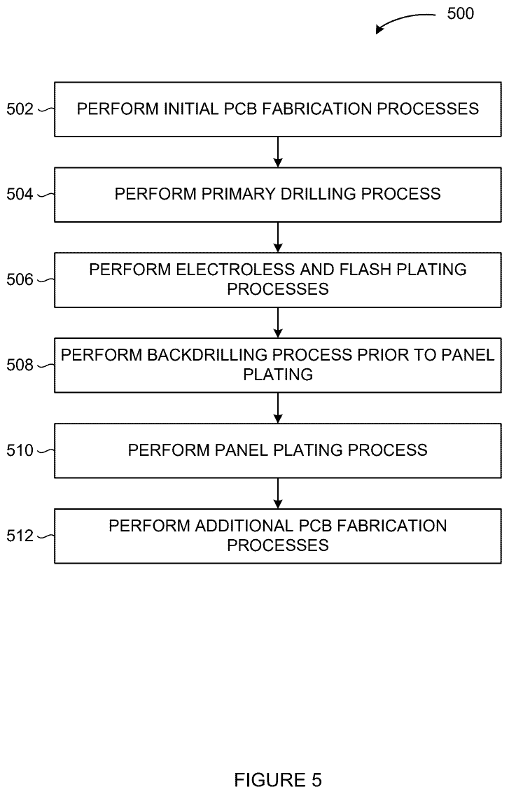

FIG. 5 is a flow diagram of method steps for fabricating a printed circuit board, according to various embodiments. The method steps can be performed by a computing system, such as computing system 600, described herein, by controlling one or more components of PCB manufacturing equipment. Additionally, or alternatively, the method steps can be performed by one or more alternative components associates with one or more processors including, without limitation, microcontrollers, RISC processors, CPUs, GPUs, DMA units, IPUs, NPUs, TPUs, NNPs, DPUs, VPUs, ASICs, FPGAs, and/or the like, in any combination. Although the method steps are described in conjunction with the systems of FIGS. 1A-4 and 6, persons of ordinary skill in the art will understand that any system configured to perform the method steps, in any order, is within the scope of the present disclosure.

As shown, a method 500 begins at step 502, where a computing system performs initial PCB fabrication processes. These processes can include fabricating nonconductive layers, applying internal signal layers to the nonconductive layers, and laminating the nonconductive layers to one another. At this stage, the PCB is a multilayer PCB with internal signal layers separated from one another by nonconductive layers but without outer signal layers.

At step 504, the computing system performs a primary drilling process on the PCB. During primary drilling, through holes, buried vias, and blind vias are initially drilled and plated as through holes and then backdrilled, as described in conjunction with step 508, to fabricate through holes, buried vias and/or blind vias. A through hole connects signal traces on both outer signal layers and optionally on one or more internal signal layers. A buried via connects signal traces on two or more internal signal layers. A blind via connects signal traces on one of the outer signal layers and signal traces on one or more internal signal layers. The computing system can control a single drill that drills holes sequentially and/or multiple drills that drill holes concurrently.

At step 506, the computing system performs electroless plating and flash plating processes on the through holes, buried vias, and blind vias of the PCB that were drilled at step 504. Electroless plating and flash plating are first plating processes performed prior to backdrilling. Electroless plating involves a chemical process to coat the inner walls of the vias, including the conductive signal traces and the nonconductive layer with metals and/or metal alloys. Flash plating involves depositing a very thin layer of metal to the electroless plated walls of the via by immersing the PCB in an electroplating bath and applying an electrical current bath.

At step 508, the computing system performs a backdrilling process on the PCB prior to panel plating. The backdrilling process includes drilling out metal from both sides of buried vias and from one side of blind vias to remove the portion of the vias that do not connect to signal traces. These portions of the vias result from the first plating processes and the second plating processes but do not provide any signal connectivity. However, these portions of the vias can generate or be susceptible to electromagnetic interference. The backdrilling process drills the unused portion of the vias to a depth sufficient to remove metal or metal alloy from the walls of buried vias and blind vias. The depth of backdrilling can be close to or at the depth of the buried vias and blind vias that connect to signal traces on inner signal layers. The length of the remaining stubs after backdrilling is 1 mil+2 mils /−1 mil, resulting in a minimum length of 0 mils and a maximum length of 3 mils.

At step 510, the computing system performs a panel plating process on the through holes, buried vias, and blind vias of the PCB. Panel plating is a second plating process performed subsequent to backdrilling. Panel plating is performed after backdrilling to apply a thick metal or metal alloy layer to the via, thereby improving conduction and durability. Because the depth of backdrilling performed at step 508 can be close to or at the depth of the inner signal layers, the electrical paths between the buried vias, blind vias, and respective signal traces can be subject to damage. Any damage resulting from backdrilling can be repaired by the panel plating process.

At step 512, the computing system performs additional PCB fabrication processes. These processes can include applying a solder mask to the PCB, filling and insulating the resulting vias with an epoxy resin, as well as other subsequent processes. At this stage, the PCB is a multilayer PCB with internal signal layers and outer signal layers separated from one another by nonconductive layers.

The method 500 then terminates. Alternatively, the method 500 returns to step 502 to fabricate additional PCBs.

### System Overview

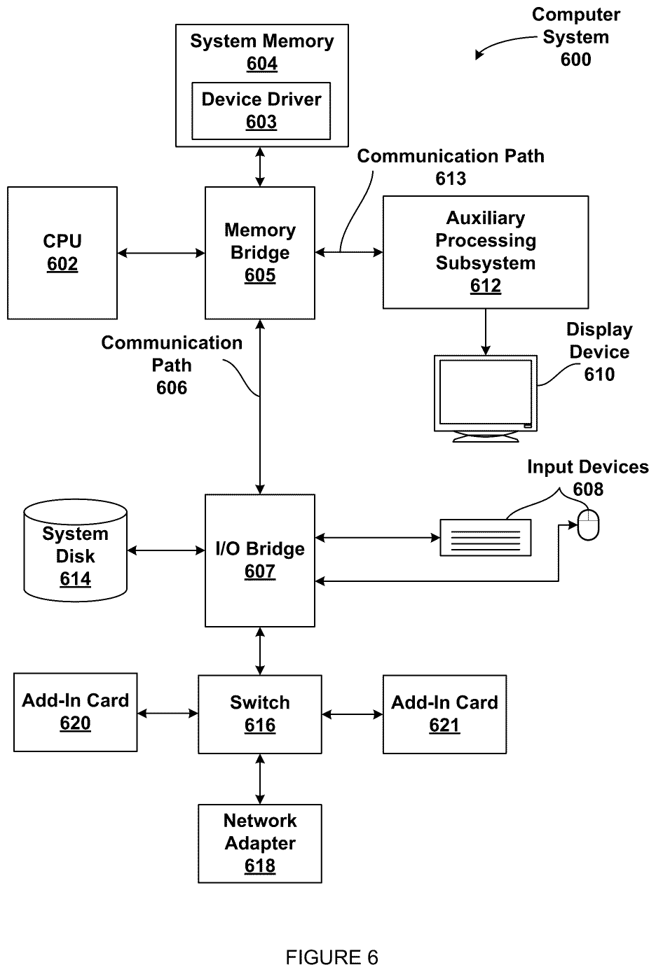

FIG. 6 is a block diagram of a computing system 600 configured to implement one or more aspects of the various embodiments. As shown, computing system 600 includes, without limitation, a central processing unit (CPU) 602 and a system memory 604 coupled to an auxiliary processing subsystem 612 via a memory bridge 605 and a communication path 613. Memory bridge 605 is further coupled to an I/O (input/output) bridge 607 via a communication path 606, and I/O bridge 607 is, in turn, coupled to a switch 616.

In operation, I/O bridge 607 is configured to receive user input information from input devices 608, such as a keyboard or a mouse, and forward the input information to CPU 602 for processing via communication path 606 and memory bridge 605. In some examples, input devices 608 are employed to verify the identities of one or more users in order to permit access of computing system 600 to authorized users and deny access of computing system 600 to unauthorized users. Switch 616 is configured to provide connections between I/O bridge 607 and other components of the computing system 600, such as a network adapter 618 and various add-in cards 620 and 621. In some examples, network adapter 618 serves as the primary or exclusive input device to receive input data for processing via the disclosed techniques.

As also shown, I/O bridge 607 is coupled to a system disk 614 that may be configured to store content and applications and data for use by CPU 602 and auxiliary processing subsystem 612. As a general matter, system disk 614 provides non-volatile storage for applications and data and may include fixed or removable hard disk drives, flash memory devices, and CD-ROM (compact disc read-only-memory), DVD-ROM (digital versatile disc-ROM), Blu-ray, HD-DVD (high definition DVD), or other magnetic, optical, or solid state storage devices. Finally, although not explicitly shown, other components, such as universal serial bus or other port connections, compact disc drives, digital versatile disc drives, film recording devices, and the like, may be connected to I/O bridge 607 as well.

In various embodiments, memory bridge 605 may be a Northbridge chip, and I/O bridge 607 may be a Southbridge chip. In addition, communication paths 606 and 613, as well as other communication paths within computing system 600, may be implemented using any technically suitable protocols, including, without limitation, Peripheral Component Interconnect Express (PCIe), HyperTransport, or any other bus or point-to-point communication protocol known in the art.

In some embodiments, auxiliary processing subsystem 612 comprises a graphics subsystem that delivers pixels to a display device 610 that may be any conventional cathode ray tube, liquid crystal display, light-emitting diode display, or the like. In such embodiments, the auxiliary processing subsystem 612 incorporates circuitry optimized for graphics and video processing, including, for example, video output circuitry. Such circuitry may be incorporated across one or more auxiliary processors included within auxiliary processing subsystem 612. An auxiliary processor includes any one or more processing units that can execute instructions such as a reduced instruction set computer (RISC) processor, central processing unit (CPU), a parallel processing unit (PPU), a graphics processing unit (GPU), a direct memory access (DMA) unit, an intelligence processing unit (IPU), a neural processing unit (NAU), a tensor processing unit (TPU), a neural network processor (NNP), a data processing unit (DPU), a vision processing unit (VPU), an application specific integrated circuit (ASIC), a field-programmable gate array (FPGA), and/or the like.

In some embodiments, auxiliary processing subsystem 612 includes two processors, referred to herein as a primary processor (normally a CPU) and a secondary processor. Typically, the primary processor is a CPU and the secondary processor is a GPU. Additionally, or alternatively, each of the primary processor and the secondary processor may be any one or more of the types of auxiliary processors disclosed herein, in any technically feasible combination. The secondary processor receives secure commands from the primary processor via a communication path that is not secured. The secondary processor accesses a memory and/or other storage system, such as such as system memory 604, Compute eXpress Link (CXL) memory expanders, memory managed disk storage, on-chip memory, and/or the like. The secondary processor accesses this memory and/or other storage system across an insecure connection. The primary processor and the secondary processor may communicate with one another via a GPU-to-GPU communications channel, such as Nvidia Link (NVLink). Further, the primary processor and the secondary processor may communicate with one another via network adapter 618. In general, the distinction between an insecure communication path and a secure communication path is application dependent. A particular application program generally considers communications within a die or package to be secure. Communications of unencrypted data over a standard communications channel, such as PCIe, are considered to be unsecure.

In some embodiments, the auxiliary processing subsystem 612 incorporates circuitry optimized for general purpose and/or compute processing. Again, such circuitry may be incorporated across one or more auxiliary processors included within auxiliary processing subsystem 612 that are configured to perform such general purpose and/or compute operations. In yet other embodiments, the one or more auxiliary processors included within auxiliary processing subsystem 612 may be configured to perform graphics processing, general purpose processing, and compute processing operations. System memory 604 includes at least one device driver 603 configured to manage the processing operations of the one or more auxiliary processors within auxiliary processing subsystem 612.

In various embodiments, auxiliary processing subsystem 612 may be integrated with one or more other the other elements of FIG. 6 to form a single system. For example, auxiliary processing subsystem 612 may be integrated with CPU 602 and other connection circuitry on a single chip to form a system on chip (SoC).

It will be appreciated that the system shown herein is illustrative and that variations and modifications are possible. The connection topology, including the number and arrangement of bridges, the number of CPUs 602, and the number of auxiliary processing subsystems 612, may be modified as desired. For example, in some embodiments, system memory 604 could be connected to CPU 602 directly rather than through memory bridge 605, and other devices would communicate with system memory 604 via memory bridge 605 and CPU 602. In other alternative topologies, auxiliary processing subsystem 612 may be connected to I/O bridge 607 or directly to CPU 602, rather than to memory bridge 605. In still other embodiments, I/O bridge 607 and memory bridge 605 may be integrated into a single chip instead of existing as one or more discrete devices. Lastly, in certain embodiments, one or more components shown in FIG. 6 may not be present. For example, switch 616 could be eliminated, and network adapter 618 and add-in cards 620, 621 would connect directly to I/O bridge 607.

Computing system 600 can be configured to control various components of manufacturing equipment to automate one or more steps to fabricate PCBs. In that regard, computing system 600 can be configured to control manufacturing equipment to fabricate and laminate conductive signal layers and nonconductive layers, to drill one or more vias, to perform electroless plating and/or flash plating on the vias, to perform backdrilling to reduce or eliminate stubs, to perform panel plating on the backdrilled vias, to apply epoxy to the plated vias, and to perform various other PCB fabrication processes.

The PCBs fabricated using the systems and methods described herein may be used by, without limitation, non-autonomous vehicles, semi-autonomous vehicles (e.g., in one or more adaptive driver assistance systems (ADAS)), piloted and un-piloted robots or robotic platforms, warehouse vehicles, off-road vehicles, vehicles coupled to one or more trailers, flying vessels, boats, shuttles, emergency response vehicles, motorcycles, electric or motorized bicycles, aircraft, construction vehicles, underwater craft, drones, and/or other vehicle types. Further, the systems and methods described herein may be used for a variety of purposes, by way of example and without limitation, for machine control, machine locomotion, machine driving, synthetic data generation, model training, perception, augmented reality, virtual reality, mixed reality, robotics, security and surveillance, simulation and digital twinning, autonomous or semi-autonomous machine applications, deep learning, environment simulation, object or actor simulation and/or digital twinning, data center processing, conversational AI, light transport simulation (e.g., ray-tracing, path tracing, etc.), collaborative content creation for 3D assets, cloud computing and/or any other suitable applications.

The PCBs fabricated using the disclosed embodiments may be comprised in a variety of different systems such as automotive systems (e.g., a control system for an autonomous or semi-autonomous machine, a perception system for an autonomous or semi-autonomous machine), systems implemented using a robot, aerial systems, medial systems, boating systems, smart area monitoring systems, systems for performing deep learning operations, systems for performing simulation operations, systems for performing digital twin operations, systems implemented using an edge device, systems incorporating one or more virtual machines (VMs), systems for performing synthetic data generation operations, systems implemented at least partially in a data center, systems for performing conversational AI operations, systems for performing light transport simulation, systems for performing collaborative content creation for 3D assets, systems implemented at least partially using cloud computing resources, and/or other types of systems.

In sum, techniques are disclosed for fabricating a printed circuit board (PCB) that includes vias. A PCB is fabricated to include one or more outer signal layers and one or more inner signal layers that are separated from one another by a nonconductive material. Vias are formed by drilling a hole at a location where two or more signal traces on different signal layers meet. The vias are drilled through the PCB from one outer signal layer to the other outer signal layer. One or more first plating processes, such as electroless plating and flash plating, apply a thin layer of metal or metal alloy to the inside walls of the vias. If the via does not connect to signal traces on both outer signal layers of the PCB, then the via is backdrilled from an outer signal layer that does not connect to a signal trace toward an inner signal layer that does connect to a signal trace. The backdrilling process can leave a stub disposed between an inner signal layer and an outer signal layer. The stub can have a nominal length of 1 mil and a tolerance of +2 mil /−1 mil. As a result, the remaining stub length can range from a minimum of 0 mil (no stub) to a maximum of 3 mil.

Backdrilling close to the inner signal layer may result in minor damage to the inner signal layer connection from the via to the signal trace. This minor damage, if present, can be repaired by a subsequent second plating process, such as panel plating. Panel plating is performed after backdrilling to apply a thick metal or metal alloy layer to the via, thereby improving conduction and durability. An epoxy resin is applied to fill and insulate the resulting via, and subsequent other processes are performed to complete fabrication of the PCB.

At least one technical advantage of the disclosed techniques relative to the prior art is that, with the disclosed techniques, the stub length of a via can be significantly reduced relative to conventional approaches. As a result, the vias generated by the disclosed backdrilling techniques can generate less electromagnetic interference and can be less susceptible to electromagnetic interference relative to backdrilling after panel plating is completed. These advantages represent one or more technological improvements over prior art approaches.

1. In some embodiments, a method for fabricating a printed circuit board (PCB) comprises: performing a first plating process on a via disposed between a first outer signal layer of the PCB and a second outer signal layer of the PCB; performing a first backdrilling process on the via from the first outer signal layer of the PCB to a first inner signal layer of the PCB; and subsequent to performing the first backdrilling process on the via, performing a second plating process on the via.

2. The method according to clause 1, wherein: the via comprises a stub that is disposed between the first outer signal layer and the first inner signal layer, and the stub has a nominal length of 1 mil.

3. The method according to clause 1 or clause 2, wherein: the via comprises a stub that is disposed between the first outer signal layer and the first inner signal layer, and the stub has a minimum length of 0 mils and a maximum length of 3 mils.

4. The method according to any of clauses 1-3, further comprising: performing a second backdrilling process on the via from the second outer signal layer of the PCB to a second inner signal layer of the PCB, wherein the second plating process is performed on the via subsequent to performing the second backdrilling process on the via.

5. The method according to any of clauses 1-4, wherein: the via comprises a first stub that is disposed between the first outer signal layer and the first inner signal layer, the via further comprises a second stub that is disposed between the second outer signal layer and the second inner signal layer, and each of the first stub and the second stub has a nominal length of 1 mils.

6. The method according to any of clauses 1-5, wherein: the via comprises a first stub that is disposed between the first outer signal layer and the first inner signal layer, the via further comprises a second stub that is disposed between the second outer signal layer and the second inner signal layer, and each of the first stub and the second stub has a minimum length of 0 mils and a maximum length of 3 mils.

7. The method according to any of clauses 1-6, further comprising: prior to performing the first plating process on the via, performing a first drilling process to form the via between the first outer signal layer and the second outer signal layer.

8. The method according to any of clauses 1-7, further comprising: subsequent to performing the second plating process on the via, applying an epoxy resin to the via.

9. In some embodiments, a printed circuit board (PCB), comprises: a first outer signal layer; a second outer signal layer; a first inner signal layer; and a via disposed between the first outer signal layer and the second outer signal layer, wherein: the via comprises a first stub that is disposed between the first outer signal layer and the first inner signal layer, and the first stub has a nominal length of 1 mil.

10. The PCB according to clause 9, wherein: the first stub has a minimum length of 0 mils and a maximum length of 3 mils.

11. The PCB according to clause 9 or clause 10, further comprising: a second inner signal layer, wherein the via further comprises a second stub that is disposed between the second outer signal layer and the second inner signal layer.

12. The PCB according to any of clauses 9-11, wherein: the second stub has a nominal length of 1 mil.

13. The PCB according to any of clauses 9-12, wherein: each of the first stub and the second stub has a minimum length of 0 mils and a maximum length of 3 mils.

14. In some embodiments, a printed circuit board (PCB), comprises: a plurality of signal layers including at least a first outer signal layer and a first inner signal layer; and a via disposed between the plurality of signal layers, wherein: the via comprises a first stub extending from the first inner signal layer towards the first outer signal layer, and the first stub has a nominal length of 1 mil.

15. The PCB according to clause 14, wherein: the first stub has a minimum length of 0 mils and a maximum length of 3 mils.

16. The PCB according to clause 14 or clause 15, wherein the plurality of signal layers comprises a second outer signal layer and a second inner signal layer.

17. The PCB according to any of clauses 14-16, wherein: the via further comprises a second stub extending from the second inner signal layer towards the second outer signal layer.

18. The PCB according to any of clauses 14-17, wherein: each of the first stub and the second stub has a nominal length of 1 mil.

19. The PCB according to any of clauses 14-18, wherein: each of the first stub and the second stub has a minimum length of 0 mils and a maximum length of 3 mils.

20. The PCB according to any of clauses 14-19, wherein: the first stub is disposed between the first outer signal layer and the first inner signal layer.

Any and all combinations of any of the claim elements recited in any of the claims and/or any elements described in this application, in any fashion, fall within the contemplated scope of the present disclosure and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method, or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module” or “system.” Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods, and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A method for fabricating a printed circuit board (PCB), the method comprising:
performing a first plating process on a via disposed between a first outer signal layer of the PCB and a second outer signal layer of the PCB;
performing a first backdrilling process on the via from the first outer signal layer of the PCB to a first inner signal layer of the PCB; and
subsequent to performing the first backdrilling process on the via, performing a second plating process on the via.

2. The method of claim 1, wherein:
the via comprises a stub that is disposed between the first outer signal layer and the first inner signal layer, and
the stub has a nominal length of 1 mil.

3. The method of claim 1, wherein:
the via comprises a stub that is disposed between the first outer signal layer and the first inner signal layer, and
the stub has a minimum length of 0 mils and a maximum length of 3 mils.

4. The method of claim 1, further comprising:
performing a second backdrilling process on the via from the second outer signal layer of the PCB to a second inner signal layer of the PCB,
wherein the second plating process is performed on the via subsequent to performing the second backdrilling process on the via.

5. The method of claim 4, wherein:
the via comprises a first stub that is disposed between the first outer signal layer and the first inner signal layer,
the via further comprises a second stub that is disposed between the second outer signal layer and the second inner signal layer, and
each of the first stub and the second stub has a nominal length of 1 mils.

6. The method of claim 4, wherein:
the via comprises a first stub that is disposed between the first outer signal layer and the first inner signal layer,
the via further comprises a second stub that is disposed between the second outer signal layer and the second inner signal layer, and
each of the first stub and the second stub has a minimum length of 0 mils and a maximum length of 3 mils.

7. The method of claim 1, further comprising:
prior to performing the first plating process on the via, performing a first drilling process to form the via between the first outer signal layer and the second outer signal layer.

8. The method of claim 1, further comprising:
subsequent to performing the second plating process on the via, applying an epoxy resin to the via.

9. A printed circuit board (PCB), comprising:
a first outer signal layer;
a second outer signal layer;
a first inner signal layer; and
a via disposed between the first outer signal layer and the second outer signal layer,
wherein:
the via comprises a first stub that is disposed between the first outer signal layer and the first inner signal layer, and
the first stub has a nominal length of 1 mil.

10. The PCB of claim 9, wherein:
the first stub has a minimum length of 0 mils and a maximum length of 3 mils.

11. The PCB of claim 9, further comprising:
a second inner signal layer,
wherein the via further comprises a second stub that is disposed between the second outer signal layer and the second inner signal layer.

12. The PCB of claim 11, wherein:
the second stub has a nominal length of 1 mil.

13. The PCB of claim 11, wherein:
each of the first stub and the second stub has a minimum length of 0 mils and a maximum length of 3 mils.

14. A printed circuit board (PCB), comprising:
a plurality of signal layers including at least a first outer signal layer and a first inner signal layer; and
a via disposed between the plurality of signal layers,
wherein:
the via comprises a first stub extending from the first inner signal layer towards the first outer signal layer, and
the first stub has a nominal length of 1 mil.

15. The PCB of claim 14, wherein:
the first stub has a minimum length of 0 mils and a maximum length of 3 mils.

16. The PCB of claim 14, wherein the plurality of signal layers comprises a second outer signal layer and a second inner signal layer.

17. The PCB of claim 16, wherein:
the via further comprises a second stub extending from the second inner signal layer towards the second outer signal layer.

18. The PCB of claim 17, wherein:
each of the first stub and the second stub has a nominal length of 1 mil.

19. The PCB of claim 17, wherein:
each of the first stub and the second stub has a minimum length of 0 mils and a maximum length of 3 mils.

20. The PCB of claim 14, wherein:
the first stub is disposed between the first outer signal layer and the first inner signal layer.
